(19) United States
(12) Patent Application Publication
(10) Pub. No.: US 2024/0191359 A1
(43) Pub. Date: Jun. 13, 2024

(54) ETCHING METHOD AND PROCESSING DEVICE

(71) Applicant: Tokyo Electron Limited, Minato-ku, Tokyo (JP)

(72) Inventor: Toshio HASEGAWA, Nirasaki City, Yamanashi (JP)

(21) Appl. No.: 18/554,225

(22) PCT Filed: Apr. 4, 2022
(86) PCT No.: PCT/JP2022/017030

§ 371 Date: Oct. 6, 2023

(30) Foreign Application Priority Data
Apr. 15, 2021 (JP) 2021-069287

(51) Int. Cl. C23F 1/12

(52) U.S. Cl. CPC C23F 1/12

(57) ABSTRACT

Provided is a method for etching a metal on a substrate, the etching method including (a) a step for exposing the metal to a halogen-containing gas and modifying a surface layer of the metal to be a halide-containing surface layer, (b) a step for exposing the halide-containing surface layer to a gas that contains carbon (C) and oxygen (O) and removing the halide-containing surface layer, and (c) a step for repeating the (a) step and the (b) step in the stated order.

### TECHNICAL FIELD

The present disclosure relates to an etching method and a processing device.

### BACKGROUND

For example, Patent Document 1 proposes etching an RuO₂ film into a desired pattern using plasma of mixed chlorine and oxygen gases.

Further, Patent Document 2 proposes a method of etching an atomic layer of metals such as tungsten and cobalt. In this method, (a) a metal surface is exposed to a halide chemical substance, in order to form a modified halide-containing surface layer. Next, (b) while exposing the modified halide-containing surface layer to plasma, a bias voltage is applied to a substrate to remove the halide-containing surface layer.

### PRIOR ART DOCUMENTS

### Patent Documents

Patent Document 1: Japanese Patent Laid-Open Publication No. 1996-078396
Patent Document 1: Japanese Patent Laid-Open Publication No. 2017-063186

The present disclosure provides a technique for etching trace amount of metals without using plasma.

### SUMMARY

According to one embodiment of the present disclosure, there is provided a method of etching a metal on a substrate, the etching method including (a) modifying a surface layer of the metal into a halide-containing surface layer by exposing the metal to a halogen-containing gas, (b) removing the halide-containing surface layer by exposing the modified halide-containing surface layer to a gas containing carbon (C) and oxygen (O), and (c) repeating the step of (a) and the step of (b) in this order.

According to one aspect, it is possible to etch trace amount of metals without using plasma.

### BRIEF DESCRIPTION OF DRAWINGS

FIG. 1 is a flowchart illustrating an example of a substrate processing method according to an embodiment.

FIGS. 2A to 2F are diagrams illustrating the substrate processing method of FIG. 1.

FIG. 3 is a flowchart illustrating an example of an ALE method according to an embodiment.

FIGS. 4A to 4C are diagrams illustrating the ALE method of FIG. 3.

FIG. 5 is a flowchart illustrating another example of a substrate processing method according to an embodiment.

FIGS. 6A to 6D are diagrams illustrating an ALE method of FIG. 5.

FIG. 7 is a diagram illustrating an example of a processing system for executing several embodiments.

FIG. 8 is a schematic diagram illustrating an example configuration of a processing apparatus for executing several embodiments.

### DETAILED DESCRIPTION

Hereinafter, embodiments for carrying out the present disclosure will be described with reference to the drawings. In each drawing, the same reference numerals may be given to the same components, and redundant descriptions may be omitted.

### [Substrate Processing Method]

Ruthenium (Ru) is receiving attention as a low-resistance metal wiring material alternative to copper (Cu). For example, a ruthenium film is used instead of copper in a logic backend wiring layer. When forming the ruthenium film in a desired region, there are cases where a trace amount of ruthenium also adheres to a region where film formation is not desired.

In the selective film formation of ruthenium, when a ruthenium film is formed in a region where film formation is not desired, a substrate processing method is required to minimize damage to the ruthenium film formed in a desired region while removing a trace amount of ruthenium from the region where film formation is not desired.

Therefore, in a substrate processing method of the present disclosure, it is proposed to use an atomic layer etching (ALE: Atomic Layer Deposition) method of metal for etching a trace amount of ruthenium film formed in an undesired region without using plasma. In some embodiments, the ALE method of the present disclosure allows for high-precision etching down to the atomic level, i.e., within the range of about 1 Å to 10 Å per cycle. ALE is a method for removing ruthenium from an undesired region using sequential self-controlled reactions. In addition, the present disclosure focuses on the etching of a ruthenium film formed in an undesired region. However, a removal target metal is not limited to ruthenium. In the substrate processing method of the present disclosure, trace amounts of metals may be etched by ALE without using plasma.

In one example, ALE may include the respective following steps: (1) supplying a halogen-containing gas, (2) purging the halogen-containing gas from a processing container, (3) supplying a gas containing C and O, and (4) purging the gas containing C and O from the processing container.

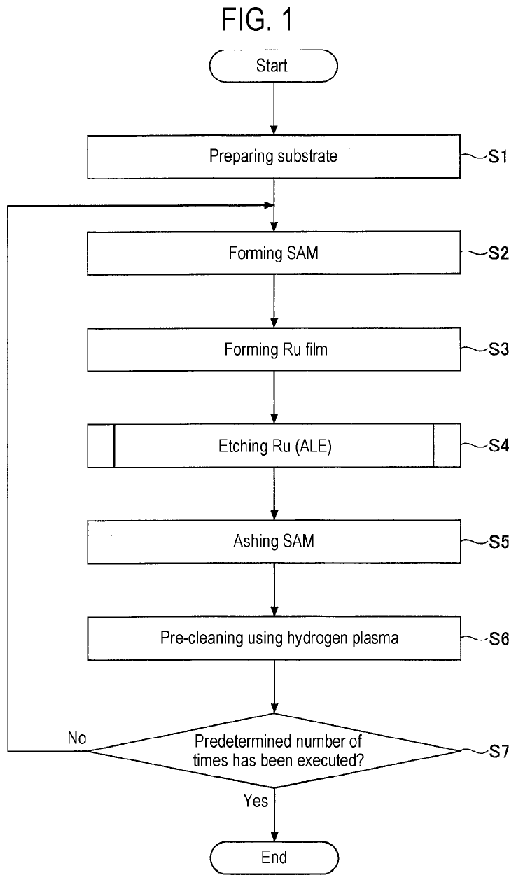

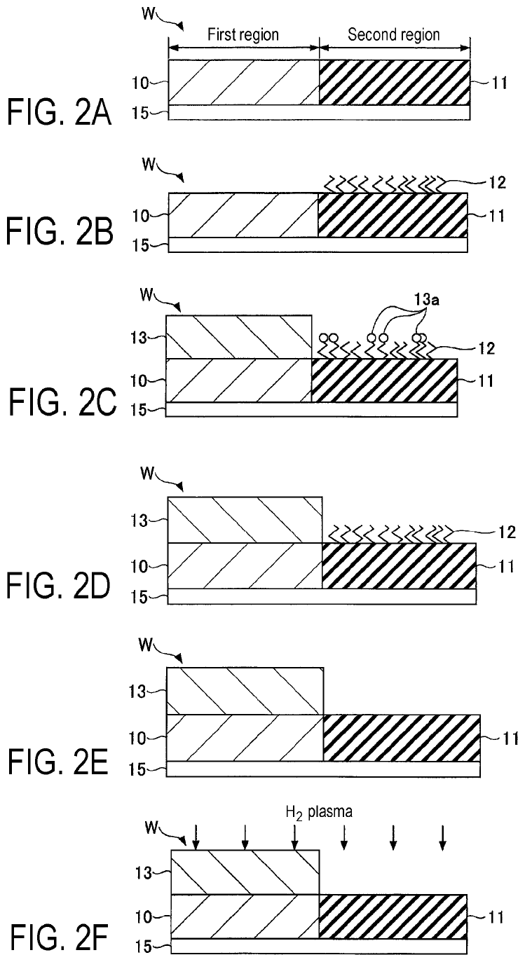

Hereinafter, the substrate processing method including the ALE method described above will be described with reference to FIGS. 1 and 2A to 2F. FIG. 1 is a flowchart illustrating an example of a substrate processing method according to an embodiment. FIGS. 2A to 2F are diagrams illustrating the substrate processing method of FIG. 1.

When the process of FIG. 1 is initiated, a substrate W is loaded into a processing container, and the substrate W is placed on a stage for preparation (step S1). For example, the prepared substrate W has a film formed thereon as illustrated in FIG. 2A. In the example of the substrate W in FIG. 2A, the substrate has, on a silicon substrate 15, a first region with a metal film 10 and a second region with a dielectric film 11.

Next, a self-assembled monolayer (hereinafter referred to as “SAM 12”) as an inhibitor is formed on the dielectric film 11 (step S2). A silane-based compound (silane coupling agent) or the like is used as an example of a precursor for the SAM 12. However, the precursor is not limited to this as long as it is a precursor capable of functioning as an inhibitor on the dielectric film 11. Thus, as illustrated in FIG. 2B, the SAM 12 is selectively formed on the dielectric film 11 in the second region, while the SAM 12 is not formed on the metal film 10 in the first region.

In this state, a ruthenium film is then formed (step S3). The SAM 12 inhibits the formation of a metal film. Therefore, the ruthenium film 13 is hardly formed in the second region and is selectively formed on the metal film 10 in the first region. For example, the ruthenium film is formed by using ruthenium carbonyl (Ru₃(CO)₁₂) as a precursor and thermally decomposing it on a wafer by thermal CVD. However, the precursor is not limited to this as long as it is a precursor capable of forming a ruthenium film. Thus, as illustrated in FIG. 2C, the ruthenium film 13 is selectively formed on the metal film 10 in the first region, and the formation of the ruthenium film on the dielectric film 11 in the second region is inhibited by the SAM 12.

However, a trace amount of ruthenium 13a is also formed in (adheres to) the second region during the formation of the ruthenium film 13. In FIG. 2C, the trace amount of ruthenium 13a is formed in the second region.

Next, ruthenium is etched by ALE (step S4). In step S4, ALE is used to etch and remove the trace amount of ruthenium 13a in the second region. Thus, as illustrated in FIG. 2D, the ruthenium 13a is removed from the second region. In addition, in step S4, a surface of the ruthenium film 13 on the metal film 10 is also slightly etched. However, due to atomic-level etching, the ruthenium film 13 in the first region, where film formation is desired, is limitingly etched on the surface, which results in minimal damage to the ruthenium film 13.

Next, an 02 gas and H₂ gas are supplied and plasmarized such that the SAM 12 is ashed by oxygen plasma and hydrogen plasma (step S5). Thus, as illustrated in FIG. 2E, the SAM 12 is removed from the second region.

Next, a H₂ gas is supplied and plasmarized such that the surfaces of the ruthenium film 13 in the first region and the dielectric film 11 in the second region are pre-cleaned using hydrogen plasma (step S6). In step S5, the surfaces of the ruthenium film 13 and the dielectric film 11 are oxidized by the oxygen plasma. Therefore, as illustrated in FIG. 2F, a surface oxide layer of the ruthenium film 13 is removed by reduction using the hydrogen plasma. Further, surface purification, such as the removal of adsorbed halogen from the surfaces of the ruthenium film 13 and the dielectric film 11, is performed. In addition, the pre-cleaning may be executed after step S1.

Next, it is determined whether a predetermined number of times has been executed (step S7). The predetermined number of times is defined in advance as one or more times. The predetermined number of times is determined based on the thickness of the ruthenium film 13. The higher the thickness of the formed ruthenium film 13, the larger the predetermined number of times is set.

When it is determined in step S7 that the predetermined number of times has not been executed, the process returns to step S2 and the execution of steps S2 to S7 is repeated. When it is determined in step S7 that the predetermined number of times has been executed, this process is terminated. Thus, it becomes possible to selectively form the ruthenium film 13 having a predetermined thickness on the metal film 10 while inhibiting the film formation of ruthenium on the dielectric film 11.

### [ALE]

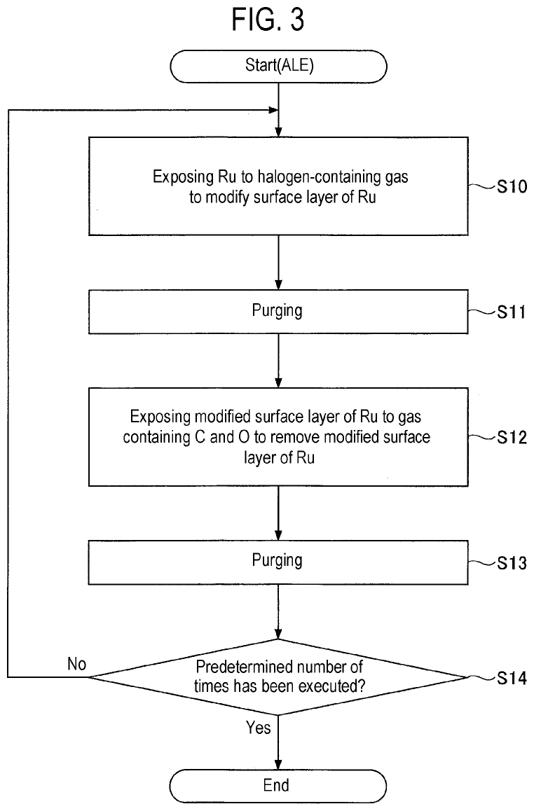

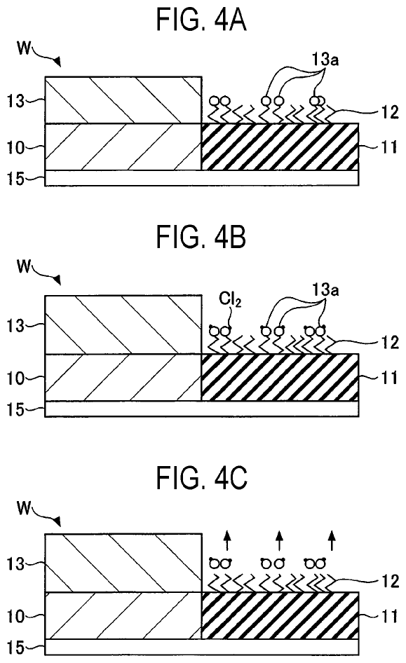

Next, the etching of ruthenium by ALE executed in step S4 will be described with reference to FIGS. 3 and 4A to 4C. FIG. 3 is a flowchart illustrating an example of an ALE method according to an embodiment. FIGS. 4A to 4C are diagrams illustrating the ALE method of FIG. 3.

The process of FIG. 3 is initiated as a result of being invoked from step S4 of FIG. 1. In this process, a halogen-containing gas is initially supplied so that ruthenium (ruthenium 13a and ruthenium film 13) is exposed to the halogen-containing gas, thereby modifying a surface layer of the ruthenium into a halide-containing surface layer (step S10).

The halogen-containing gas contains at least one of chlorine (Cl), fluorine (F), bromine (Br), or iodine (I). For example, the halogen-containing gas may include at least one of Cl₂, SOCl, F₂, HF, CF₄, C₄F₈, Br₂, HBr, I₂, HI, (COCl)₂, or (COBr)₂.

As illustrated in FIG. 4A, when the ruthenium film 13 is formed in the first region, the trace amount of ruthenium 13a is formed in the second region. In step S10, a Cl₂ gas, which is a reactive gas, is supplied to as an example of the halogen-containing gas the substrate W. FIG. 4B illustrates that, as an example, some chlorine adsorbs onto a surface of ruthenium 13a. Thus, the surface of ruthenium 13a is modified. Although some chlorine also adsorbs onto the surface of the ruthenium film 13 in the first region, this is omitted in FIGS. 4A to 4C.

FIG. 4B illustrates an example where Cl₂ adheres to a surface layer of ruthenium 13a to chlorinate it, so that the ruthenium 13a is modified into a halide (chloride)-containing surface layer. Reaction formula 1 for a case of supplying a Cl₂ gas as a halogen-containing gas is as follows:

Ru+Cl₂→RuClx(s) (Reaction formula 1)

In this case, the modified surface layer of ruthenium 13a, i.e., the halide-containing surface layer is chlorinated ruthenium (RuClx). In another example, in step S10, when a F₂ gas, which is a reactive gas, is supplied as an example of the halogen-containing gas to the substrate W, thereby modifying the surface of ruthenium 13a, some fluorine adsorbs onto the surface of ruthenium 13a. This causes the surface layer of ruthenium 13a to be modified by fluorination. As such, the types of halogen-containing gas supplied in step S10 lead to the modification of different types of halide-containing surface layers. In other words, the state of modification (chlorination, fluorination, bromination, etc.) of the halide-containing surface layer varies based on one type of halogen-containing gas or combinations thereof supplied in step S10.

Next, a N₂ gas is supplied to purge the halogen-containing gas from the processing container (step S11). However, the purge gas is not limited to the N₂ gas, and may be an inert gas such as an Ar gas.

Next, a gas containing C and O is supplied so that the modified halide-containing surface layer (surface layer of ruthenium) is exposed to the gas containing C and O, thereby removing the surface layer of ruthenium (step S12).

The gas containing C and O includes at least one of CO, CH₂O, CCl₂O, CBr₂O, CI₂O, COCl₂, or (COBr)₂. In step S12, the gas containing C and O is used to carbonylate and remove the modified halide-containing surface layer.

FIG. 4C illustrates an example of removing the modified halide-containing surface layer by carbonylation. Reaction formula 2 for a case of supplying a CO gas as the gas containing C and O is as follows:

RuClx(s)+CO→Ru₃(CO)₁₂(g)+Cl₂(g)/Ru(CO)Cl(g) (Reaction formula 2)

In addition, Cl₂(g)/Ru(CO)Cl(g) refers to Cl₂(g) and/or Ru(CO)Cl(g).

At this time, the halide-containing surface layer is in a chlorinated state or the like, which makes it susceptible to carbonylation. Therefore, as represented in Reaction formula 2, the halide-containing surface layer is carbonylated into ruthenium carbonyl (Ru₃(CO)₁₂(g)) with a high vapor pressure, which facilitates easy volatilization.

Next, a N₂ gas is supplied to purge the gas containing C and O from the processing container (step S13). However, the purge gas is not limited to the N₂ gas and may be an inert gas such as an Ar gas.

Next, it is determined whether a predetermined number of times has been executed (step S14). The predetermined number of times is the number of repetitions of atomic layer etching, and is determined in advance as one or more times. When it is determined in step S14 that the predetermined number of times has not been executed, the process returns to step S10 and the execution of steps S10 to S14 is repeated. When it is determined in step S14 that the predetermined number of times has been executed, this process is terminated. Thus, it becomes possible to remove the ruthenium 13a formed in the second region.

The ALE method is atomic layer level etching, and achieves uniform etching of ruthenium by the self-control of a surface reaction. Therefore, the ALE process of FIG. 3 achieves high controllability of etching while limiting the amount of ruthenium removed in one cycle of steps S10 to S13, thus enabling etching of a trace amount of ruthenium without rapid over-etching. This may realize a low damage process for the ruthenium film 13 as a result of removing the ruthenium 13a in the second region, where film formation is not desired, and limitingly etching only the surface of the ruthenium film 13 in the first region where film formation is desired.

### [Substrate Processing Method Without Forming SAM]

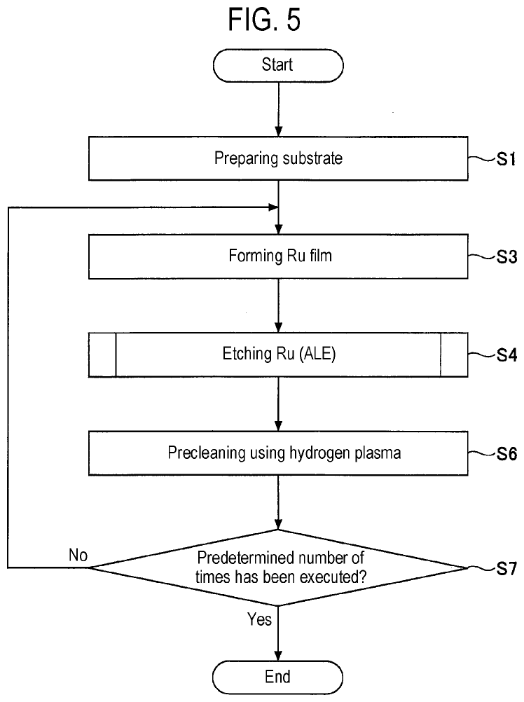

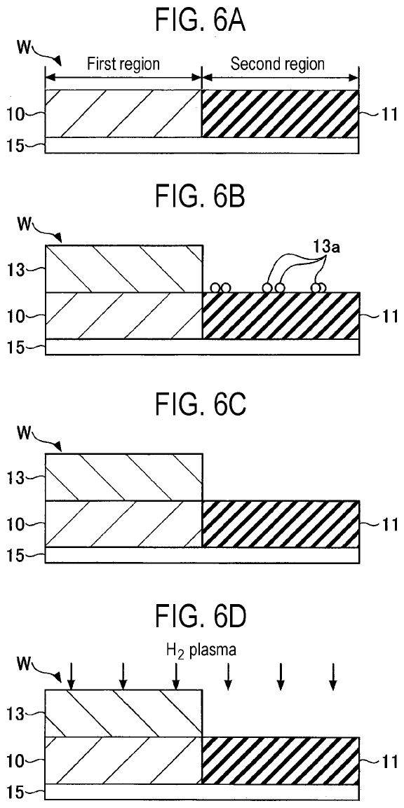

Next, a substrate processing method without forming the SAM 12 will be described with reference to FIGS. 5 and 6A to 6D. FIG. 5 is a flowchart illustrating another example of a substrate processing method according to an embodiment. FIGS. 6A to 6D are diagrams illustrating an ALE method of FIG. 5. In addition, if the step numbers in FIG. 5 match those in FIG. 1, they indicate the same processes.

For example, when utilizing a process allowing for selective film formation only on a metal film such as a chemical vapor deposition (CVD) process of forming a film using a carbonylated ruthenium precursor, the substrate processing method without forming the SAM 12 as illustrated in FIG. 5 may be executed.

However, even in this case, there are cases where a trace amount of ruthenium is formed on the dielectric film 11. Therefore, in this case as well, the ruthenium formed on the dielectric film 11 is removed using the ALE method of FIG. 3. Hereinafter, the substrate processing method without forming the SAM 12 will be described.

When the process of FIG. 5 is initiated, the substrate W is loaded into the processing container, and the substrate W is placed on the stage for preparation (step S1). For example, the prepared substrate W has a film formed thereon as illustrated in FIG. 6A. In the example of FIG. 6A, similar to the example of FIG. 2A, the substrate W has, on the silicon substrate 15, the first region with the metal film 10 and the second region with the dielectric film 11.

In this state, the ruthenium film 13 is then formed on the metal film 10 using a process that enables selective formation only on the metal film 10 (step S3). Thus, as illustrated in FIG. 6B, the ruthenium film 13 is selectively formed on the metal film 10 in the first region. At this time, the trace amount of ruthenium 13a is also formed on the dielectric film 11 in the second region.

Next, the ruthenium is etched by ALE (step S4). In step S4, the ruthenium 13a in the second region is etched and removed using the ALE method of FIG. 3 described above. Thus, as illustrated in FIG. 6C, the ruthenium 13a is removed from the second region. In addition, in step S4, a surface of the ruthenium film 13 on the metal film 10 is also slightly etched. However, due to atomic-level etching, the ruthenium film 13 in the first region, where film formation is desired, is limitingly etched on the surface, which results in minimal damage to the ruthenium film 13.

Next, a H₂ gas is supplied and plasmarized such that the ruthenium film 13 in the first region and the dielectric film 11 in the second region are pre-cleaned using hydrogen plasma (step S6). Thus, as illustrated in FIG. 6D, surface purification, such as the removal of adsorbed halogen from the surfaces of the ruthenium film 13 in the first region and the dielectric film 11 in the second region, is performed using the hydrogen plasma. In addition, the pre-cleaning may be executed after step S1.

Next, it is determined whether a predetermined number of times has been executed (step S7). When it is determined in step S7 that the predetermined number of times has not been executed, the process returns to step S3 and the execution of steps S3, S4, S6, and S7 is repeated. When it is determined in step S7 that the predetermined number of times has been executed, this process is terminated. Thus, it becomes possible to selectively form the ruthenium film 13 on the metal film 10 while inhibiting the film formation of ruthenium on the dielectric film 11.

In the substrate processing method illustrated in FIGS. 6A to 6D, in order not to form the SAM 12, step S2 (formation of the SAM 12) and step S5 (ashing of the SAM 12) in FIG. 1 are not performed, as compared with the substrate processing method illustrated in FIG. 1. This may contribute to the optimization of processing efficiency.

As described above, in the ALE-based etching (step S4) of the substrate processing method according to the present disclosure as illustrated in FIGS. 1 and 5, the halogen-containing gas is supplied to cause fluorination, chlorination or the like of the surface layer of ruthenium. This modification makes the halide-containing surface layer that is more reactive to the subsequently supplied gas containing C and O, i.e., easier to undergo carbonylation.

Next, the gas containing C and O is supplied, and the halide-containing surface layer is carbonylated by the gas containing C and O. In other words, the gas containing C and O is used to replace a chlorinated or fluorinated portion of the halide-containing surface layer with CO such that the halide-containing surface layer is carbonylated. This carbonylated halide-containing surface layer has a high vapor pressure, making it easily volatile. The substrate processing method of the present disclosure may be performed without using plasma.

### [Etching Target Film]

In the substrate processing method of the present disclosure, an etching target film is not limited to a ruthenium film. The etching target film may be formed of a metal selected from metal elements belonging to groups 4 to 10 in the periodic table. For example, the etching target film may contain any metal such as Ru, W, Mn, Fe, Co, Ni, Rh, Mo, V, Cr, Os, Ti, or Re.

The substrate processing method of the present disclosure may be applied to a metal material that undergoes carbonylation (a material containing a carbonyl group). For example, the above-mentioned metal is not limited to Ru—CO, and may also include W—CO, Mn—CO, Fe—CO, Co—CO, Ni—CO, Rh—CO, Mo—CO, V—CO, Cr—CO, Os—CO, Ti—CO, or Re—CO. Therefore, the substrate processing method of the present disclosure may be applied to these metal materials.

### [Etching Temperature]

During the execution of the ALE method, it is permissible to control the temperature of the stage on which the substrate W is placed so that the temperature of the substrate W ranges from 50 degrees C. to 500 degrees C. More particularly, it is permissible to control the temperature of the stage so that the temperature of the substrate W ranges from 150 degrees C. to 350 degrees C. during the execution of the ALE method.

### [Processing System]

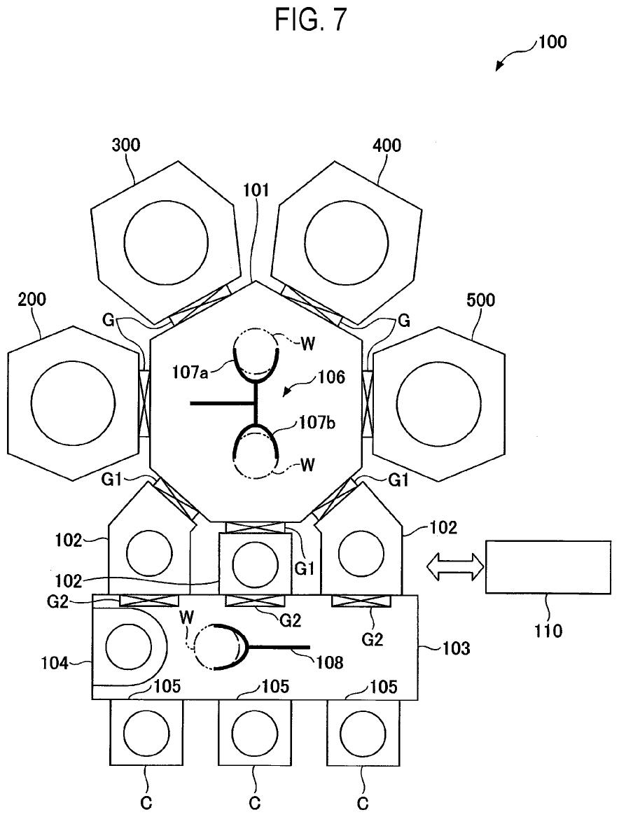

A configuration example of a processing system 100 for performing a substrate processing method according to some embodiments will be described with reference to FIG. 7. The processing system 100 includes a processing apparatus 200 for forming the SAM 12, a processing apparatus 300 for forming a ruthenium film, a processing apparatus 400 for performing ALE-based etching, and a processing apparatus 500 for ashing and pre-cleaning the SAM 12. These processing apparatuses 200 to 500 are connected to a vacuum transfer chamber 101 via gate valves G, respectively. The interior of the vacuum transfer chamber 101 is evacuated by a vacuum pump and is maintained at a predetermined degree of vacuum.

Three load lock chambers 102 are connected to the vacuum transfer chamber 101 via gate valves G1, respectively. An atmospheric transfer chamber 103 is connected on the opposite side of the vacuum transfer chamber 101 via gate valves G2, respectively, with the load lock chambers 102 interposed therebetween. The load lock chambers 102 perform pressure control between the atmosphere and the vacuum when transferring the substrate W between the atmospheric transfer chamber 103 and the vacuum transfer chamber 101.

Three ports 105 for the attachment of carriers C (e.g., FOUPs) in which the substrate W is accommodated are provided on the wall of the atmospheric transfer chamber 103 opposite to the wall where the load lock chambers 102 are attached. Further, an alignment container 104 for the alignment of the silicon substrate W is provided on the sidewall of the atmospheric transfer chamber 103. A downflow of clean air is created inside the atmospheric transfer chamber 103.

A transfer mechanism 106 is provided inside the vacuum transfer chamber 101. The transfer mechanism 106 transfers the substrate W to and from the processing apparatuses 200 to 500 and the load lock chambers 102. The transfer mechanism 106 has two transfer arms 107a and 107b which are independently movable.

A transfer mechanism 108 is provided inside the atmospheric transfer chamber 103. The transfer mechanism 108 transfers the substrate W to and from the carriers C, the load lock chambers 102, and the alignment container 104. The transfer mechanism 108 has a transfer arm.

The processing system 100 includes a controller 110. The controller 110 controls drive systems, such as each component of the processing apparatuses 200 to 500, an exhaust mechanism or the transfer mechanism 106 of the vacuum transfer chamber 101, an exhaust mechanism or gas supply mechanism of the load lock chambers 102, the transfer mechanism 108 of the atmospheric transfer chamber 103, and the gate valves G, G1 and G2. The controller 110 has a CPU (computer), a memory, and the like. The CPU causes the processing system 100 to execute a predetermined operation based on recipes stored in the memory.

The substrate W is retrieved from the carrier C connected to the atmospheric transfer chamber 103 by the transfer arm of the transfer mechanism 108, and is then loaded into one of the load lock chambers 102. The interior of the load lock chamber 102 is evacuated. Subsequently, the substrate W is retrieved from the load lock chamber 102 by the transfer arm of the transfer mechanism 106, and is then loaded into the processing apparatus 200, so that the SAM 12 is formed on the substrate W. In the substrate processing method without forming the SAM 12, the formation of the SAM 12 by the processing apparatus 200 is skipped.

Thereafter, the substrate W is unloaded by the transfer arm of the transfer mechanism 106, and is loaded into the processing apparatus 300, so that the ruthenium film 13 is formed. Thereafter, the substrate W is unloaded by the transfer arm of the transfer mechanism 106, and is loaded into the processing apparatus 400, so that the ruthenium film is etched using ALE.

Thereafter, the substrate W is unloaded by the transfer arm of the transfer mechanism 106, and is loaded into the processing apparatus 500, so that the ashing and pre-cleaning of the SAM 12 are performed. In the substrate processing method without forming the SAM 12, only pre-cleaning is performed in the processing apparatus 500.

Once each process in the processing apparatuses 200 to 500 is executed a predetermined number of times, the substrate W is unloaded by the transfer arm of the transfer mechanism 106 and is loaded into one of the load lock chambers 102. The interior of the load lock chamber 102 is returned to the atmosphere, and the substrate W is returned from the load lock chamber 102 to the carrier C.

The above-described processes are performed concurrently for a plurality of substrates W, thus completing the formation of a ruthenium wiring on a predetermined number of substrates W.

### [Processing Apparatus]

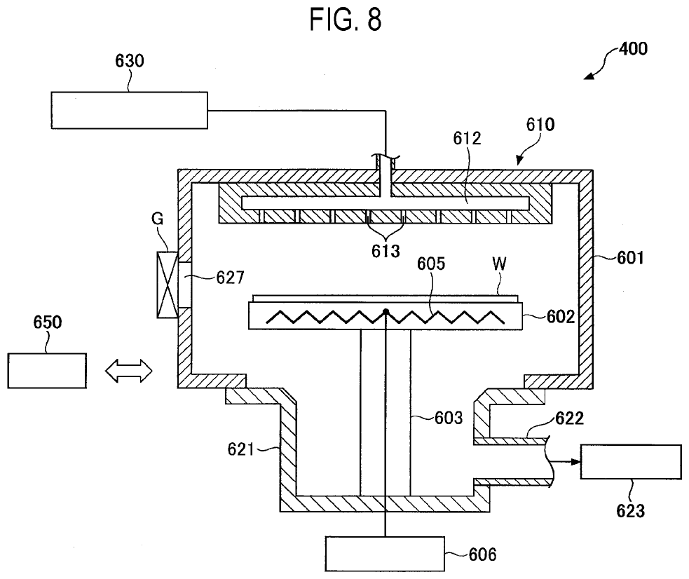

A configuration example of the processing apparatus 400 for performing ALE according to some embodiments will be described with reference to FIG. 8. The processing apparatus 400 has a vacuum processing container (hereinafter referred to as “processing container 601”). A stage 602 on which the substrate W is placed is arranged inside the processing container 601. The stage 602 is supported by a support member 603, and a heater 605 is built in the stage 602. The heater 605 is controlled by the supply of power from a heater power supply 606 to heat the substrate W to a predetermined temperature.

A shower head 610 is provided on a ceiling wall of the processing container 601 to supply gases, such as a halogen-containing gas and a gas containing C and O, from a gas supplier 630 into the processing container 601. A gas diffusion space 612 is defined inside the shower head 610, and a large number of gas discharge holes 613 communicating with the gas diffusion space 612 are formed in a bottom surface of the shower head 610.

An exhaust chamber 621 is provided on a bottom wall of the processing container 601. An exhaust pipe 622 is connected to the side surface of the exhaust chamber 621, and an exhaust device 623 having components such as a vacuum pump and a pressure control valve is connected to the exhaust pipe 622. The interior of the processing container 601 reaches a predetermined reduced pressure (vacuum) state by operating the exhaust device 623.

A loading/unloading port 627 is provided on the sidewall of the processing container 601 for loading and unloading the substrate W into and from the vacuum transfer chamber 101. The loading/unloading port 627 is opened and closed by the gate valve G.

The processing apparatus 400 includes a controller 650 that controls each component thereof such as, for example, the heater power supply 606, the exhaust device 623, and a valve and a mass flow controller of the gas supplier 630. The controller 650 controls each component in response to a command from the controller 110.

With this configuration, in the processing apparatus 400, the gate valve G is opened, and the substrate W is loaded into the processing container 601 through the loading/unloading port 627 and is placed on the stage 602. The temperature of the stage 602 is controlled so that the temperature of the substrate ranges from 50 degrees C. to 500 degrees C., more particularly from 150 degrees C. to 350 degrees C. Further, the exhaust device 623 evacuates the interior of the processing container 601 to adjust the internal pressure of the processing container 601 to a vacuum state.

Next, from the gas supplier 630, (1) the supply of a halogen-containing gas, (2) the supply of a N₂ gas (purging of the halogen-containing gas from the processing container 601), (3) the supply of a gas containing C and O, and (4) the supply of a N₂ gas (purging of the gas containing C and O from the processing container 601) are performed in this order, and the ALE cycle from (1) to (4) is performed a predetermined number of times.

According to the processing system 100, the processing apparatuses 200 to 500 execute consecutive substrate processes, completing the formation of the ruthenium film 13. This allows for an improvement in productivity.

As described above, according to the etching method of the present embodiment, it is possible to etch and remove a trace amount of ruthenium formed in an undesired second region while minimizing damage to the ruthenium film 13 formed in the first region through ALE.

The etching method and the processing apparatus according to the embodiments disclosed herein should be considered to be exemplary and not limitative in all respects. The embodiment may be modified and improved in various forms without departing from the scope of the appended claims and their gist. The items described in the above multiple embodiments may also take other configurations within a range that is not contradictory, and may be combined within a range that is not contradictory.

This application claims the priority of basic application No. 2021-69287 filed on Apr. 15, 2021 to the Japan Patent Office, and the contents of which are fully incorporated herein by reference.

### EXPLANATION OF REFERENCE NUMERALS

10: metal film, 11: dielectric film, 12: SAM, 13: ruthenium film, 13a: ruthenium, 100: processing system, 200 to 400: processing apparatus

1. An etching method of etching a metal on a substrate, the etching method comprising:
(a) modifying a surface layer of the metal into a halide-containing surface layer by exposing the metal to a halogen-containing gas;
(b) removing the halide-containing surface layer by exposing the halide-containing surface layer to a gas containing carbon (C) and oxygen (O); and
(c) repeating the step of (a) and the step of (b) in this order.

2. The etching method of claim 1, wherein the metal is any of metal elements belonging to groups 4 to 10 in a periodic table.

3. The etching method of claim 2, wherein the metal is any of Ru, W, Mn, Fe, Co, Ni, Rh, Mo, V, Cr, Os, Ti or Re.

4. The etching method of claim 1, wherein the halogen-containing gas contains at least one of chlorine (Cl), fluorine (F), bromine (Br), or iodine (I).

5. The etching method of claim 4, wherein the halogen-containing gas includes at least one of Cl₂, SOCl, F₂, HF, CF₄, C₄F₃, Br₂, HBr, I₂, HI, (COCl)₂, or (COBr)₂.

6. The etching method of claim 1, wherein the gas containing C and O includes at least one of CO, CH₂O, CC₂O, CBr₂O, Cl₂O, COC₂, or (COBr)₂.

7. The etching method of claim 1, wherein in the step of (b), the halide-containing surface layer is carbonylated and removed by the gas containing C and O.

8. The etching method of claim 1, wherein in the step of (a) and the step of (b), a temperature of a stage on which the substrate is placed is controlled so that a temperature of the substrate ranges from 50 degrees C. to 500 degrees C.

9. The etching method of claim 8, wherein in the step of (a) and the step of (b), the temperature of the stage is controlled so that the temperature of the substrate ranges from 150 degrees C. to 350 degrees C.

10. A processing device comprising a processing container and a controller that controls a method of etching a metal on a substrate in the processing container,
wherein the controller controls a process including:
(a) modifying a surface layer of the metal into a halide-containing surface layer by exposing the metal to a halogen-containing gas;
(b) removing the halide-containing surface layer by exposing the halide-containing surface layer to a gas containing carbon (C) and oxygen (O); and
(c) repeating the step of (a) and the step of (b) in this order.
